(19) United States
(12) Patent Application Publication
(10) Pub. No.: US 2008/0258182 A1
(43) Pub. Date: Oct. 23, 2008

(54) Bicmos Compatible Jfet Device and Method of Manufacturing Same

(75) Inventors: Prabhat Agarwal, Brussels (BE); Jan W. Slotboom, Eersel (NL); Wibo Van Noort, Wappingers Falls, NY (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/577,311

(22) PCT Filed: Oct. 13, 2005
(86) PCT No.: PCT/IB05/53366

§ 371 Date: Apr. 25, 2008

(30) Foreign Application Priority Data
Oct. 14, 2004 (NL) 04 105037.8

(51) Int. Cl. H01L 29/808; H01L 21/8232; H01L 21/337

(52) U.S. Cl. 257/256; 438/186; 438/189; 257/E21.606; 257/E29.312; 257/E21.446

(57) ABSTRACT

A BiCMOS-compatible JFET device comprising source and drain regions (17, 18) which are formed in the same process as that used to form the emitter out-diffusion or a vertical bipolar device, wherein the semiconductor layer which forms the emitter cap in the bipolar device forms the channel (16) of the JFET device and the layer of material (i.e. the base epi-stack) which forms the intrinsic base region of the bipolar device forms the intrinsic gate region (14) of the JFET device. As a result, the integration of the JFET device into a standard BiCMOS process can be achieved without the need for any additional masking or other processing steps.

This invention relates generally to BiCMOS processes for fabricating integrated circuits and, more particularly, to a JFET device, and a method of manufacturing same, which is compatible with standard BiCMOS processes.

Modern integrated circuits for high performance RF applications conventionally rely on semiconductor processes that include a vertical bipolar junction transistor, along with conventional CMOS processes.

Traditionally, in integrated circuit design, JFETs function field effect transistors), which are unipolar devices, can be used as good followers, because of their high input impedance and improved cut-off frequencies and low noise Figures relative to MOS (metal-oxide semiconductor) field effect transistors. On the other hand, JFETs are not such good amplifiers as bipolar transistors, because in bipolar transistors, the transconductance is proportional to the emitter current, whereas in JFETs the transconductance is proportional to the square root of the drain current.

The so-called BiCMOS processes, which tend to be used to fabricate vertical bipolar devices, cater to high-end RF solutions. On the other hand, JFET devices are frequently used in applications where noise performance is critical, and may provide an ideal solution in areas such as satellite receivers, or car radar systems, where the low noise front-end currently tends to be a discrete III/V device.

In spite of the fact that it is often highly desirable to use other devices, such as JFETs, in such high-end RF solutions, so as to take advantage of certain qualities thereof, it can be difficult and costly to integrate other devices, particularly JFETs into the standard BiCMOS processes, because this requires extra masking and implantation steps.

U.S. Pat. No. 4,939,099 describes a process for obtaining a JFET in a BiCMOS process, whereby the JFET source and drain regions are formed simultaneously with a vertical bipolar transistor emitter region, and the JFET gate contact region is formed simultaneously with a vertical bipolar base contact region. However, additional steps are required in the fabrication of the JEFET, including an implantation step to form a top gate region and another implantation step to create a JFET channel region, which steps must be performed separately from the process for fabricating the vertical bipolar transistor, thereby increasing the complexity and cost of the standard BiCMOS process.

We have now devised an improved arrangement, and it is an object of the present invention to provide a method of fabricating a JFET device in a BiCMOS process, whereby no additional masking or other processing steps are necessarily required to be performed.

In accordance with the present invention, there is provided a method of fabricating a JFET device, the method comprising providing a semiconductor substrate, epitaxially depositing a first layer of semiconductor material of a first conductivity type on said substrate, and providing a second, relatively lightly-doped, layer of semiconductor material of a second conductivity type over said first layer, forming first and second diffused, relatively highly-doped regions of said second conductivity type in said second layer, wherein said first layer of material forms an internal gate region of said device, said first and second diffused regions forms a source and drain region respectively of said device, and said second layer of material forms a channel between said source and said drain regions.

Also in accordance with the present invention, there is provided a JFET device, comprising a substrate on which is epitaxially deposited a first layer of semiconductor material of a first conductivity type, a second, relatively lightly-doped layer of semiconductor material of a second conductivity type being provided over said first layer of material, and diffused, relatively highly-doped source and drain regions of said second conductivity type being provided in said second layer of material, wherein said first layer of material forms the internal gate of said device and said second layer of material forms the channel between said source and drain regions.

Still further in accordance with the present invention, there is provided a method of fabricating an integrated circuit in a BiCMOS process, the method comprising providing a substrate having a first region for supporting a vertical bipolar device and a second region for supporting a JFET device, said first region defining a collector region of a second conductivity type, the method comprising epitaxially depositing a first layer of semiconductor material of a first conductivity type on said substrate at said first and second regions thereof, providing a second, relatively lightly-doped layer of semiconductor material of a first conductivity type over said first layer of material, forming at least one, relatively highly-doped diffused region of said second conductivity type in said second layer of material at said first region, and forming at least two, relatively highly-doped diffused regions of said second conductivity type in said second layer of material at said second region, wherein said first layer of material forms an internal base region in respect of said vertical bipolar device at said first region and an internal gate region in respect of said JFET device at said second region, said at least one diffused region at said first region of said substrate forms an emitter of said vertical bipolar device and said at least two diffused regions at said second region of said substrate form source and drain regions respectively of said JFET device, and said second layer of material forms an emitter cap in respect of said vertical bipolar device and a channel between said source and drain regions of said JFET device.

The present invention extends to an integrated circuit fabricated according to the method defined above, and comprising at least one vertical bipolar transistor and at least one JFET device.

In view of the modified layout of the JFET device of the present invention, it is possible to integrate such a device in a standard BiCMOS process without any additional masking or other processing steps being required.

Preferably, the step of forming said diffused regions is performed substantially simultaneously in respect of both said first and second regions of said substrate.

In a preferred embodiment, the first layer of semiconductor material comprises SiGe or SiGe:C. The addition of Germanium enables the formation of high performance heterojunction bipolar transistors which can operate at speeds much higher than standard silicon bipolar transistors. In fact, such SiGe HBT's have been found to operate at speeds previously attainable only with gallium arsenide, yet have the advantage of being built in existing silicon fabs using standard silicon production tooling. The SiGe devices are also relatively easily integrated into standard CMOS logic technologies. Silicon Germanium:Carbon (SiGe:C), formed by adding small amounts of Germanium (Ge) and Carbon I to silicon, results in a heterojunction bipolar transistor offering still higher unity gain frequency, lower-noise Figure, higher collector current and better linearity than the conventional silicon bipolar transistor. Although the noise Figure of the resulting SiGe: C HBT devices is lower than that of conventional Si devices, the noise performance of the proposed additional JFET is still better and such performance is required and desired.

The step of forming said at least two diffused regions in respect of the JFET device beneficially includes the steps of providing at least two respective dummy emitters on said second layer of semiconductor material and providing a spacer in respect of each said dummy emitter, wherein the spacers overlap by a predetermined distance. The spacing between the spacers should ideally be large enough to accommodate the minimum space between two poly-emitter areas (i.e. between the source and the drain of the JFET device), including two times the minimum overlap for sufficient overlay and etching tolerance.

These and other aspects of the present invention will be apparent from, and elucidated with reference to, the embodiments described herein.

Embodiments of the present invention will now be described by way of example only and with reference to the accompanying drawings, in which:

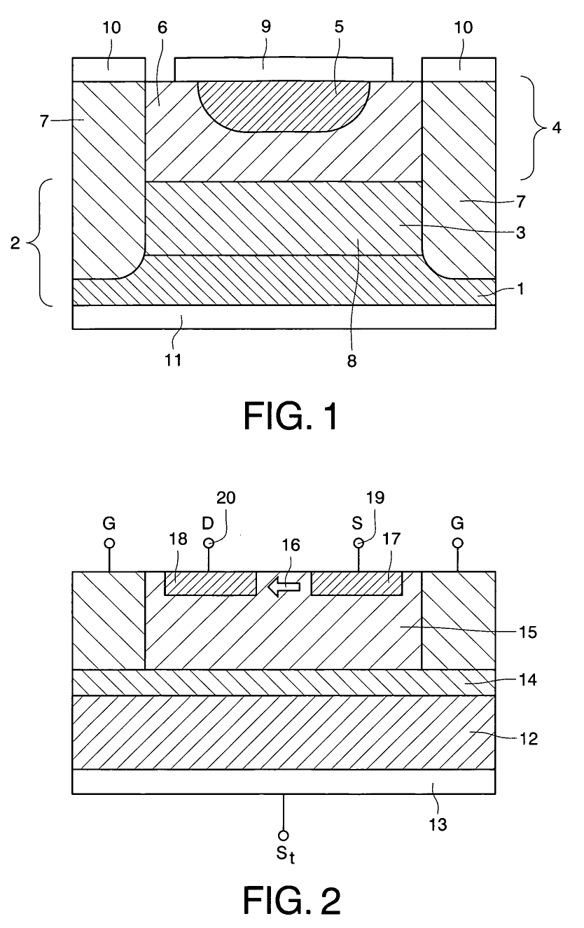

FIG. 1 is a schematic cross-sectional view of a vertical bipolar transistor according to the prior art;

FIG. 2 is a schematic cross-sectional view of a JFET device according to an exemplary embodiment of the present invention;

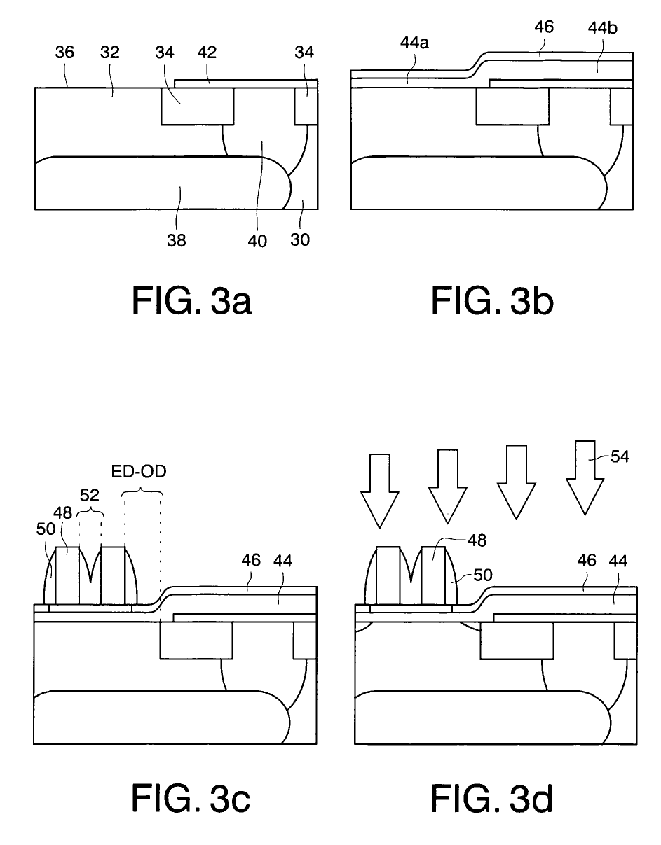

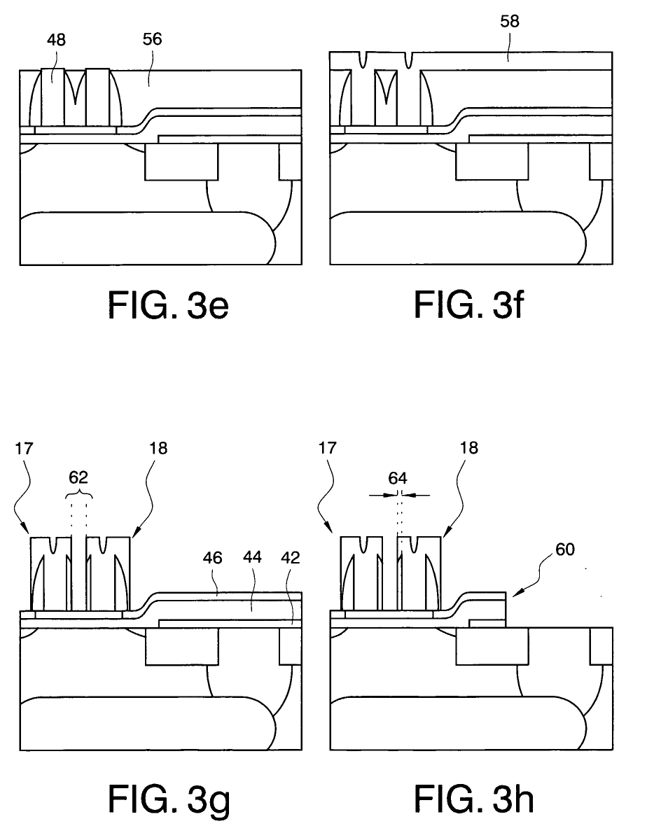

FIGS. 3a-3h illustrate schematically the principal steps involved in fabricating a JFET device according to an exemplary embodiment of the present invention;

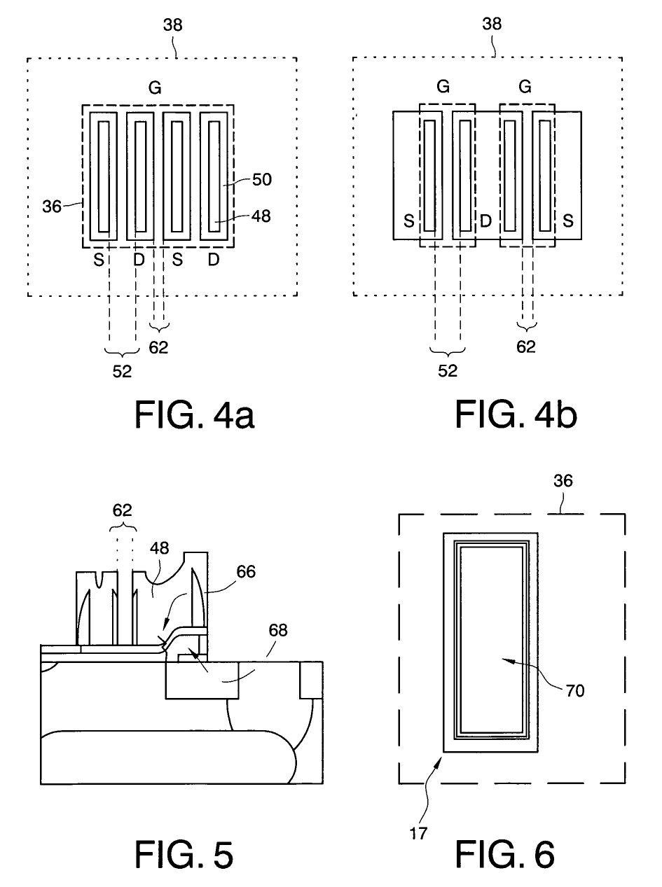

FIGS. 4a and 4b illustrate schematically some alternative layouts for JFET devices according to two respective exemplary embodiments of the present invention;

FIG. 5 is a schematic cross-sectional view of a JFET device according to an exemplary embodiment of the present invention, having the layout illustrated in FIG. 4b;

FIG. 6 is a schematic plan view of a portion of the device of FIG. 5 with cutout in the source connection; and

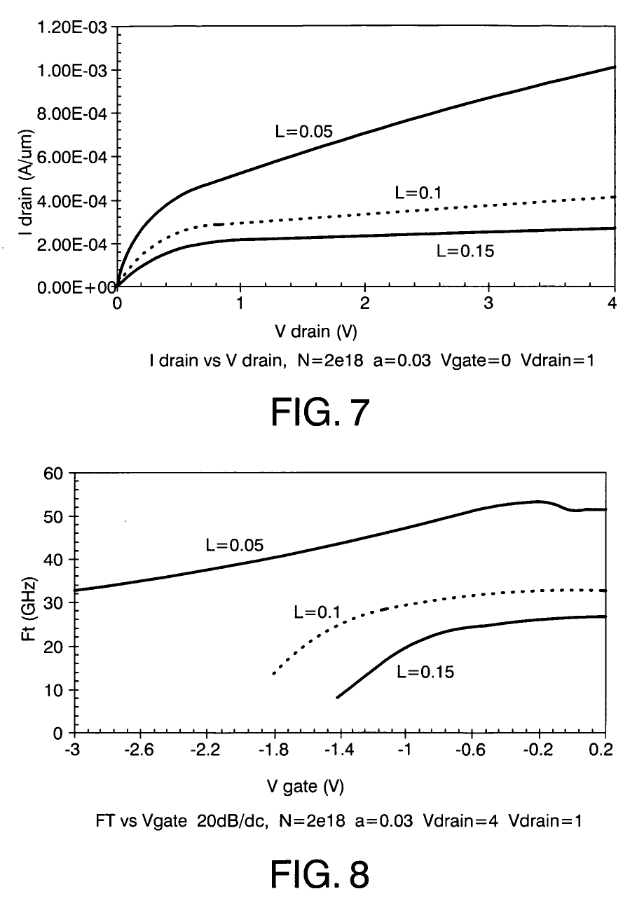

FIGS. 7 and 8 are graphical illustrations of the DC characteristics of a JFET device according to an exemplary embodiment of the present invention, for different channel lengths.

Referring to FIG. 1 of the drawings, there is illustrated the structure of a vertical bipolar device resulting from a standard HBT (Heterojunction Bipolar Transistor) process, which provides a very high performance transistor structure and is built using more than one semiconductor material, thereby taking advantage of the different bandgaps of the semiconductors used to form the base, emitter and collector. The illustrated device comprises a substrate 1 which also forms a heavily doped region of the n-type collector 2, and the collector 2 further comprising a lightly doped, so-called drift region 3. The n-type emitter 4 comprises a heavily doped region 5 (the so-called “emitter-out” diffusion) and a weakly doped region 6 (or so-called n-type “emitter cap”). The respective doping concentrations of the emitter regions 5, 6 might be of the order of, for example, 10²⁰ at/cm³ and 10⁸ at/cm³. An implanted extrinsic, heavily-doped p-type base region 7 is provided bordering the surface of the semiconductor body, and a buried or intrinsic, heavily-doped p-type base region 8 is located below the emitter region, which intrinsic base region may be formed of, for example, SiGe or SiGeC. Connection conductors 9, 10 and 11 are provided in respect of the emitter 4, base and collector 2 respectively.

Referring to FIG. 2 of the drawings, there is illustrated schematically a lateral JFET device having a layout according to the invention and comprising a substrate 12 having a buffer 13, wherein a p-type intrinsic gate layer 14 is provided on the substrate 12. An n-type depletion region 15 supports the channel (denoted by arrow 16) of the device and heavily doped n-type source and drain regions 17, 18 are provided in the n-type depletion region 15. Due to the proposed new layout, it is possible to form the source and drain regions 17, 18 using the same process as that used to form the n+ emitter out-diffusion 5 of the bipolar device. Further, the channel 16 of the JFET device can be formed using the same process as that used to form the n-type emitter cap 6 of the bipolar device, while the intrinsic gate layer 14 can be formed by the same process as that used to form the highly doped, p-type intrinsic base region 3 of the bipolar device. Still further, an implanted extrinsic, heavily-doped p-type gate region 17 is provided bordering the surface of the semiconductor body of the JFET device, and can be formed using the same process as that used to form the analogous extrinsic base connection regions 7 of the bipolar device. Finally, the source/drain contacts 19, 20 will use the same module as the emitter of the bipolar device.

An exemplary process scheme for fabricating a JFET device according to the invention will now be described in detail. However, it will be appreciated that the present invention is not necessarily limited to this process scheme and, indeed, it is envisaged that the proposed new layout of the JFET device will enable it to be integrated into many different HBT processes, without additional masking, implantation or other processing steps necessarily being required.

Referring to FIG. 3a of the drawings, a semiconductor body of silicon is taken as the basis in this exemplary embodiment, which is provided with an epitaxially grown, n-type doped layer 30. A region of monocrystalline silicon, here an active region 32, and silicon oxide regions, here field insulation regions 34, bordering on the active region 32 are formed in the layer 30 so as to border a surface 36 thereof. Furthermore, a buried, n-type doped layer 38 and a contact zone 40 are formed in a customary manner. The active area 32 is exposed by locally opening a seed layer 42.

A silicon- (or germanium-)containing layer (not shown) is deposited on the surface 36, which layer grows epitaxially in a monocrystalline manner on the monocrystalline active region 32 and in a non-monocrystalline (i.e. amorphous or polycrystalline) manner on the seed layer 42 and insulation regions 34.

Thus, referring to FIG. 3b of the drawings, after subsequent epitaxial growth, a monocrystalline base-epi stack 44a is present on the active area 32, whereas a polycrystalline layer 44b has been formed on the seed layer 42 and field oxide regions 34. An n-type emitter cap layer 46 is deposited over the layer 44. It will be appreciated that the layer 44 is commonly grown over using non-selective epitaxy, and will therefore be present over the whole wafer. The layer 46 may equally be deposited over the whole wafer. Thus, in a first region of the wafer, the layer 44 may form the intrinsic base region of a heterojunction bipolar transistor and in a second region of the wafer, the same layer 44 may form the intrinsic gate of a JFET according to the invention. Similarly, in the first region of the wafer, the layer 46 may form the emitter cap of the HBT, whereas in the second region, the same layer 46 may form the depletion region (i.e. channel) in respect of the JFET device.

The base region 46 may be formed of silicon, but is more beneficially formed of SiGe or, more preferably of SiGeC, for the reasons given above.

Next, and referring to FIG. 3c of the drawings, dummy emitters 48, each followed by a spacer 50. In respect of the first region referred to above, a single dummy emitter and spacer would be required to form the single, highly-doped emitter of the HBT, whereas in respect of the second region, two dummy emitters 48 and spacers 50 are provided, as shown in FIG. 3c so as to enable the two highly-doped source and drain regions of the JFET device to be formed. A spacing 52 between the spacers 50 is selected such that the spacers 50 overlap. The overlapping spacers block the subsequent extrinsic base (gate connection) implant (denoted by the arrows 54 in FIG. 3d) that overdopes the emitter cap 46, and protects the region between the emitters 48 where the n-type channel of the JFET device will be formed.

Next, and referring to FIG. 3e of the drawings, an isolating layer 56 is deposited and planarised, leaving the tops of the dummy emitters 48 exposed. The dummy emitters 48 and the isolating layer 56 are made of different materials, so as to facilitate the selective removal of the dummy emitter material, following which removal, the n-type emitter (source/drain) 58 is deposited using either epitaxy (for a mono emitter) or LPCVD (for a poly emitter), as shown in FIG. 3f.

FIGS. 3g and 3h illustrate the final steps, i.e. patterning of the poly emitter as shown in FIG. 3g, so as to define the source 17 and drain 18 of the JFET device, and patterning of the “base” layers to define the gate 60 of the JFET device. This is a critical step because the spacing 52 between the spacers 50 is limited by the spacer width (i.e. the spacers 50 must overlap), whereas it must be large enough to accommodate the minimum space 62 between two poly-emitter areas (i.e. between the source 17 and the drain 18 of the JFET device), including two times the minimum overlap 64 for sufficient overlay and etching tolerance. The minimum overlay tolerance in a known process is in the order of 50 nm or less, combined with a minimum printable slit of 200 nm, a minimum distance 52 between spacers of 300 nm is obtained. This means that the spacer 50 must be at least 150 nm wide (and possible a bit more for sufficient etching tolerance).

Thus, the finalised structure consists of two emitters that are used as the source 17 and drain 18 of the JFET device, and the base connection that is used as a gate 60 to pinch the n-type channel formed by the n-type emitter cap 46 between the two emitters.

As stated above, although an exemplary process flow for fabricating a JFET device according to the invention has been provided, the present invention is not necessarily limited to this integration scheme. The only requirement is a base epi-stack with a top layer of suitable conductivity type (i.e. the so-called emitter cap) that preferably has a minimum thickness of 5-10 nm. Fabrication of the JFET device requires no additional masking or processing steps relative to the fabrication of a vertical bipolar device in a BiCMOS process, which significant advantage relative to the prior art is achieved by the modification of the layout of the JFET.

Parasitic capacitance tends to be extremely critical for the device of the invention because the product of gate-source and source-drain capacitance with transconductance determine the cutoff frequency. The capacitance has a large contribution from direct overlap between the source and the gate. This is parasitic because it does not contribute to an increased transconductance.

The layout of the device is preferably optimised to minimise source-gate capacitance. Two examples are shown in FIG. 4: interdigitated (a) and emitter-over-active (b). The layout of the seed layer and the poly-base is less critical, hence it is not shown in the Figures.

The overlap capacitance of the interdigitated device illustrated in FIG. 4a, is determined by the minimum emitter size that can be fabricated (which tends to be somewhere between 100 and 200 nm). This is a poly emitter device. Note that the channel can be accessed from both sides of the stripes in the middle, hence the relative contribution of parasitic capacitance is reduced by a factor of two. Further geometrical improvement could be achieved with a dotted Source that allows access to the channel from 4 sides.

The emitter-over-active variation illustrated in FIG. 4b is another exemplary poly emitter layout, which can reduce the Source-Gate capacitance a bit more then the interdigitated layout of FIG. 4a. This option relies on the fact that, typically, diffusion of dopants is strongly enhanced in polycrystalline material. Referring additionally to FIGS. 5 and 6 of the drawings, in this layout, the emitter 48 is placed across a grain boundary 66. The part where the emitter 48 contacts polycrystalline material, will be overdoped (n-type). Ideally, the n doping will extend slightly beyond the grain boundary 66 (as shown at 68), resulting in a good passivation of the S-G junction. Now only overlay and etch tolerance must be accounted for, thus reducing the overlap capacitance even further. The layout of this approach is very similar to the interdigitated one, but the source is larger and overlaps a cutout 70 in the active area 36 (a field area).

In FIGS. 7 and 8, numerical simulations are illustrated in respect of the DC and RF behaviour of a typical JFET device according to the invention. It can be seen that the device is “normally-on”, as is frequently the case with JFET devices. Further, the dc-characteristics show no abnormalities. As a first measure of the RF performance, the unity current gain cut-off frequency, f_{T} is also calculated.

FIG. 8 shows that cut-off frequencies in the range of 50 GHz can be obtained without further optimisation.

Should it prove necessary, it may be possible to include a second gate near the top of the proposed device structure to improve the noise performance of this device. In that case the channel would be pushed away from the oxide interface near the top of the device structure, which may be a source of low-frequency noise in the device.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A method of fabricating a JFET device, the method comprising providing a semiconductor substrate,
epitaxially depositing a first layer of semiconductor material of a first conductivity type on said substrate, and providing a second, relatively lightly-doped, layer of semiconductor material of a second conductivity type over said first layer,
forming first and second diffused, relatively highly-doped regions of said second conductivity type in said second layer,
wherein said first layer of material forms an internal gate region of said device, said first and second diffused regions form a source and drain regions respectively of said device, and said second layer of material forms a channel between said source and said drain regions.

2. A JFET device, comprising
a substrate on which is epitaxially deposited a first layer of semiconductor material of a first conductivity type,
a second, relatively lightly-doped layer of semiconductor material of a second conductivity type being provided over said first layer of material, and
diffused, relatively highly-doped source and drain regions of said second conductivity type being provided in said second layer of material,
wherein said first layer of material forms the internal gate of said device and said second layer of material forms the channel between said source and drain regions.

3. A method of fabricating an integrated circuit in a BiCMOS process, the method comprising
providing a substrate having a first region for supporting a vertical bipolar device and a second region for supporting a JFET device, said first region defining a collector region of a second conductivity type,
epitaxially depositing a first layer of semiconductor material of a first conductivity type on said substrate at said first and second regions thereof,
providing a second, relatively lightly-doped layer of semiconductor material of a first conductivity type over said first layer of material,
forming at least one, relatively highly-doped diffused region of said second conductivity type in said second layer of material at said first region, and
forming at least two, relatively highly-doped diffused regions of said second conductivity type in said second layer of material at said second region,
wherein said first layer of material forms an internal base region in respect of said vertical bipolar device at said first region and an internal gate region in respect of said JFET device at said second region,
said at least one diffused region at said first region of said substrate forms an emitter of said vertical bipolar device and said at least two diffused regions at said second region of said substrate form source and drain regions respectively of said JFET device, and
said second layer of material forms an emitter cap in respect of said vertical bipolar device and a channel between said source and drain regions of said JFET device.

4. A method according to claim 3, wherein the step of forming said diffused regions is performed substantially simultaneously in respect of both said first and second regions of said substrate.

5. A method according to claim 3, wherein the first layer of semiconductor material comprises SiGe or SiGe:C.

6. A method according to claim 3, wherein the step of forming said at least two diffused regions in respect of the JFET device includes the steps of
providing at least two respective dummy emitters on said second layer of semiconductor material and
providing a spacer in respect of each said dummy emitter, wherein the spacers overlap by a predetermined distance.

7. An integrated circuit fabricated according to the method of claim 3, and comprising at least one vertical bipolar transistor and at least one JFET device.
